(19) United States
(12) Patent Application Publication
(10) Pub. No.: US 2008/0119004 A1
(43) Pub. Date: May 22, 2008

(54) METHOD OF PACKAGING A DEVICE HAVING A KEYPAD SWITCH POINT

(76) Inventors: Kenneth R. Burch, Austin, TX (US); Marc A. Mangrum, Manchaca, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/561,211

(22) Filed: Nov. 17, 2006

(51) Int. Cl. H01L 21/56

(52) U.S. Cl. 438/51; 257/E21.502

(57) ABSTRACT

A packaged device has a semiconductor device that has a first major surface and a second major surface. An encapsulating layer is formed over the second major surface and around sides of the semiconductor device. The first major surface of the semiconductor device is left exposed. The semiconductor device has the ability to perform a keypad function and has a first contact that has a surface that is external to the semiconductor device. The first contact is used in performing the keypad function. A first dielectric layer is formed over the first major surface. A second dielectric layer is formed over the second major surface. A second contact that has a surface that is external to the packaged device is connected to the first contact. A keypad can be connected to the second contact. The number of such first and second contacts is variable based on the keypad.

### CROSS-REFERENCE TO RELATED APPLICATIONS

This application is related to the following four applications assigned to the assignee hereof, by the same inventors hereof, and filed on even date herewith: 1. U.S. patent application Ser. No. ______ , docket number MT10361TK, titled METHOD OF PACKAGING A DEVICE USING A DIELECTRIC LAYER; 2. U.S. patent application Ser. No. ______ , docket number MT10412TK, titled METHOD OF PACKAGING A DEVICE HAVING A MULTI-CONTACT ELASTOMER CONNECTOR CONTACT AREA AND DEVICE THEREOF; 3. U.S. patent application Ser. No. ______ , docket number MT10285TK, titled METHOD OF PACKAGING A DEVICE HAVING A TANGIBLE ELEMENT AND DEVICE THEREOF; and 4. U.S. patent application Ser. No. ______ , docket number SC10407TK, titled METHOD OF PACKAGING A SEMICONDUCTOR DEVICE AND A PREFABRICATED CONNECTOR.

### FIELD OF THE DISCLOSURE

This disclosure relates generally to packaging a device, and more specifically, to packaging a device having a keypad switch point.

### RELATED ART

Typically, semiconductor devices are packaged for protection during operation. These packaged devices are placed on a printed circuit board (PCB) with other devices. The PCB with the devices is used in products, such as computers or cellular phones, and, in many cases, is coupled to external peripheral devices such as keypad grids to provide additional functionality, such as keypad functionality. However, the addition of these external peripheral devices may further increase the size of the products. Since there is a desire to decrease the size of products, such as computers and cellular phones, there is a need to decrease the size of the PCB and the package device without sacrificing functionality, such as the functionality provided by the external peripherals. In addition, cost is a concern. Therefore, a need exists for a cost-effective method for packaging semiconductor devices that can reduce size and increase functionality.

### BRIEF DESCRIPTION OF THE DRAWINGS

The present invention is illustrated by way of example and is not limited by the accompanying figures, in which like references indicate similar elements. Skilled artisans appreciate that elements in the figures are illustrated for simplicity and clarity and have not necessarily been drawn to scale.

FIG. 1 illustrates a cross-section of a portion of a panel including a portion of an adhesive, a first semiconductor device, and a second semiconductor device in accordance with an embodiment of the invention.

FIG. 2 illustrates the panel of FIG. 1 after forming an encapsulating layer over the first and second devices in accordance with one embodiment, the encapsulating layer having a first surface and a second surface opposite the first surface.

FIG. 3 illustrates the panel of FIG. 2 after removing the adhesive in accordance with one embodiment.

FIG. 4 illustrates the panel of FIG. 3 after forming a first dielectric layer and via-holes in the first dielectric layer in accordance with one embodiment.

FIG. 5 illustrates the panel of FIG. 4 after forming vias and interconnects and forming a second dielectric layer in accordance with one embodiment.

FIG. 6 illustrates the panel of FIG. 5 after forming vias and interconnects in the second dielectric layer in accordance with one embodiment.

FIG. 7 illustrates the panel of FIG. 6 after forming a third dielectric layer in accordance with one embodiment.

FIG. 8 illustrates the panel of FIG. 7 after forming a fourth dielectric layer over the encapsulating layer and forming via-holes in the fourth dielectric layer and extending past the first and second devices in accordance with one embodiment.

FIG. 9 illustrates the panel of FIG. 8 after forming vias and keypad switch points using the via-holes in the fourth dielectric layer in accordance with one embodiment.

FIG. 10 illustrates the panel of FIG. 9 after forming a fifth dielectric layer in accordance with one embodiment.

FIG. 11 illustrates the panel of FIG. 10 after forming openings in the fifth dielectric layer to expose the keypad switch points in accordance with one embodiment.

FIG. 12 illustrates the panel of FIG. 11 after forming openings in the third dielectric layer in accordance with one embodiment.

FIG. 13 illustrates the panel of FIG. 12 after cutting along singulation lines to singulate the panel into packaged devices in accordance with one embodiment.

FIG. 14 illustrates the singulated package of FIG. 13 after placing a keypad that is over the singulated package in accordance with one embodiment.

FIG. 15 illustrates a top-down view and in partial schematic form a keypad grid in accordance with one embodiment.

FIG. 16 illustrates a top-down view of a keypad switch point of the keypad grid of FIG. 15 in accordance with one embodiment.

FIG. 17 illustrates panel 10 after placing popple switches over the switch points in accordance with one embodiment.

FIG. 18 illustrates the panel of FIG. 17 after forming a fifth dielectric layer over the fourth dielectric layer to secure the popple switches in accordance with one embodiment.

FIG. 19 illustrates the panel of FIG. 18 after singulation in accordance with one embodiment.

### DETAILED DESCRIPTION OF THE DRAWINGS

The ability to integrate a keypad switch point grid (also referred to as a keypad grid) within a packaged device (where the packaged device may include one or more semiconductor devices, one or more discrete circuit elements, or combinations thereof) can result in smaller portable products, such as computers, cell phones, or radios. For example, these smaller portable products may allow for the realization of wrist-watch size cellular handsets, Personal Data Assistants (PDAs), remote controls, and other products that may benefit from an integrated keypad grid.

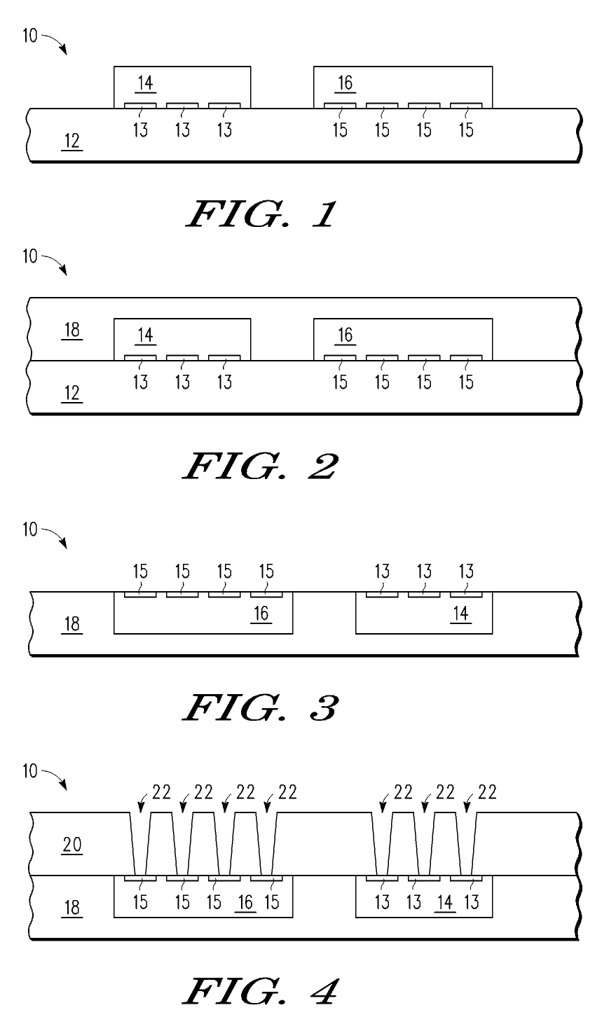

FIG. 1 illustrates a cross section of a portion of a panel 10 including a portion of an adhesive 12, a semiconductor device 14, and a semiconductor device 16 in accordance with one embodiment. Semiconductor device 14 includes contacts (e.g., pads) 13, which are exposed at a first side (i.e., a front side or a first major surface) of semiconductor device 14. Semiconductor device 16 includes contacts (e.g., pads) 15, which are exposed at a first side (i.e., a front side or a first major surface) of semiconductor device 16. Note that in the illustrated embodiment, the first side or front side of each of semiconductor device 14 and 16 correspond to the side having the active circuitry of the device, where the contacts or pads which contact to the active circuitry are located at the first or front side. Also, note that each of semiconductor devices 14 and 16 can be referred to as a semiconductor die. Also, note that the number of contacts illustrated for each semiconductor device 14 and 16 is just exemplary, and each of semiconductor device 14 and 16 may include any number of contacts. Adhesive 12, in one embodiment, is a tape. Panel 10, in one embodiment, includes a plurality aggregated sites of devices, where FIG. 1 illustrates an aggregate site including at least semiconductor devices 14 and 16. Each aggregate site of panel 10 may be identical to each other or they may not all be identical to each other. Furthermore, each aggregate site may include one or more semiconductor devices, one or more discrete devices, or one or more of any other type of devices, or combinations thereof. At some point later in the process, as will be described below, panel 10 will be singulated such that each aggregated site of panel 10 will correspond to a single packaged device; thus, in the illustrated embodiment, the package will include semiconductor devices 14 and 16. Panel 10 may be formed by placing semiconductor devices or die that have passed testing requirements, such as electrical, mechanical, or both, (i.e., known good die), discrete devices, the like, or combinations of the above on adhesive 12.

FIG. 2 illustrates panel 10 after forming an encapsulating layer 18 over a second side (i.e. a back side or a second major surface), opposite the first side, of semiconductor device 14 and a second side (i.e. a back side or a second major surface), opposite the first side, of semiconductor device 16 in accordance with one embodiment. In one embodiment, encapsulating layer 18 is a dielectric layer such as, for example, a spun-on polymer or a molding material that may be applied using any suitable process. Alternatively, encapsulating layer 18 may be any commercially available encapsulant, such as, for example, an epoxy-based and heat curable encapsulant. Because adhesive 12 is in contact with one side (e.g. the front side) of semiconductor device 14 and one side (e.g. the front side) of semiconductor device 16, encapsulating layer 18 is formed on the (five) sides of semiconductor device 14 and semiconductor device 16 that are not in contact with adhesive 12. In the embodiment shown, the five sides of semiconductor device 14 that are in contact with encapsulating layer 18 include all sides of semiconductor device 14 except the side that has contacts 13 exposed, and the five sides of semiconductor device 16 that are in contact with encapsulating layer 18 include all sides of semiconductor device 16 except the side that has contacts 15 exposed. Hence, encapsulating 18 is formed over and adjacent the sides of semiconductor device 14 and semiconductor device 16. Thus, encapsulating layer 18 is formed between semiconductor device 14 and semiconductor device 16.

FIG. 3 illustrates panel 10 after removing adhesive 12 in accordance with one embodiment. Once encapsulating layer 18 is formed, semiconductor device 14 and semiconductor device 16 are physically coupled together through the encapsulating layer 18 and thus, adhesive 12 is no longer needed. Adhesive 12 can be removed using any process, such as heat (e.g., UV light), a solvent, the like or combinations of the above. After adhesive 12 is removed, panel 10 is flipped over so that the pads 13 of semiconductor device 14 and pads 15 of semiconductor device 16 are on top and exposed. After flipping over panel 10, semiconductor device 16 in the figures is now on the opposite side of semiconductor device 14 to show the same sides of semiconductor device 16 and semiconductor device 14 that was previously illustrated.

FIG. 4 illustrates panel 10 after forming a first dielectric layer 20 over the first sides (or first major surfaces) of semiconductor device 14 and semiconductor device 16 in accordance with one embodiment. The first dielectric layer 20 may be a conventional spun-on polymer or any other suitable material formed by any suitable process, such as any suitable deposition process. In one embodiment, first dielectric layer 20 may be approximately 20 microns thick of a spun-on polymer. Note that first dielectric layer 20 is formed over the top sides of semiconductor devices 16 and 14. That is, first dielectric layer 20 is formed over the side of each of semiconductor devices 16 and 14 having exposed contacts 15 and 13, respectively. After forming first dielectric layer 20, via-holes 22 are formed by patterning and etching first dielectric layer 20 to expose at least a portion of each of contacts 15 and 13.

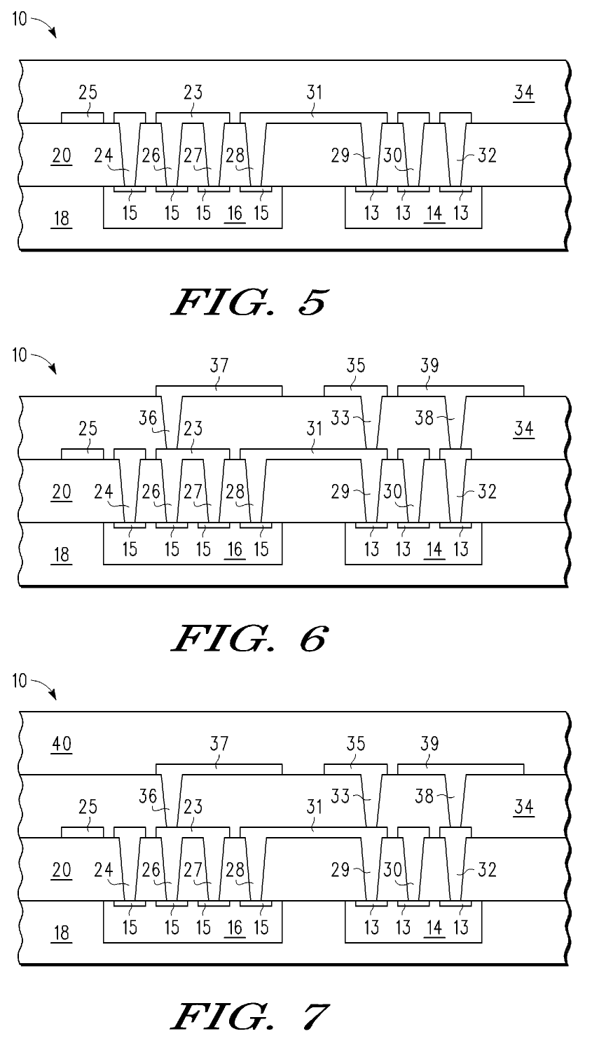

FIG. 5 illustrates panel 10 after forming vias 24, 26, 27, 28, 29, 30, and 32 to contact pads 15 and 13, as needed, in accordance with one embodiment. Vias 24, 26, 27, 28, 29, 30, and 32 are formed by filling (or at least partially filling) via-holes 22 with any conductive material, such as, for example, copper. Therefore, note that vias refer to conductor-filled via-holes (or partially conductor-filled holes) and provide electrical connections from one layer of interconnects or contacts to a different layer of interconnects or contacts. The conductive material can be deposited using any suitable process (e.g., chemical vapor deposition (CVD), atomic layer deposition (ALD), plating, the like, and combinations of the above) to fill via-holes 22 and form a thick enough material over the first dielectric layer 20. The material that lies outside vias 24, 26, 27, 28, 29, 30, and 32 and over the first dielectric layer 20 may be patterned to form the interconnects, as needed. Interconnects may electrically couple two vias, such as interconnect 23 which couples vias 26 and 27 and interconnect 31 which couples vias 28 and 29. Interconnects may also be used to route signals within a layer, as needed. For example, interconnect 25 may be an interconnect routed from via 30 or 32. Note that interconnects may travel in a direction that is in and out of the page and may provide any type of routing that is needed, such as, for example, to route signals between devices 14 and 16 or provide inputs and outputs to device 14, 16, or both. A skilled artisan recognizes that interconnects 25, 23, and 31 illustrated in FIG. 5 are merely examples of the interconnects that can be formed.

FIG. 5 also illustrates the formation of a second dielectric layer 34 over first dielectric layer 20 in accordance with one embodiment. Second dielectric layer 34 may be a spun-on polymer or another suitable material. Second dielectric layer 34 may be the same material or a different material than first dielectric layer 20 and may or may not be formed by the same process as first dielectric layer 20. Second dielectric layer 34 is formed over the interconnects 25, 23, and 31. In one embodiment, second dielectric layer 34 is approximately 20 microns thick.

FIG. 6 illustrates panel 10 after forming vias 36, 33, and 38 and interconnects 37, 35, and 39 in accordance with one embodiment, where the descriptions provided above for forming vias and interconnects apply to these vias and interconnects as well. Note that via 36 provides an electrical contact to via 26, and thus to semiconductor device 16 and via 38 provides an electrical contact to via 32, and thus to semiconductor device 14. Via 33 provides an electrical contact to via 29 (and to via 28 via interconnect 31), and thus to semiconductor devices 16 and 14. Also, interconnects 37, 35, and 39 are used to route the connections to or from vias 36, 33, and 38, respectively, as needed.

FIG. 7 illustrates panel 10 after forming a third dielectric layer 40 over second dielectric layer 34, and interconnects 37, 35, and 39, in accordance with one embodiment. Third dielectric layer 40 may be a spun-on polymer or another suitable material. Third dielectric layer 40 may be the same material or a different material than first dielectric layer 20 or second dielectric layer 34 and may or may not be formed by the same processes as first dielectric layer 20 and second dielectric layer 34. In one embodiment, third dielectric layer 40 is approximately 20 microns thick.

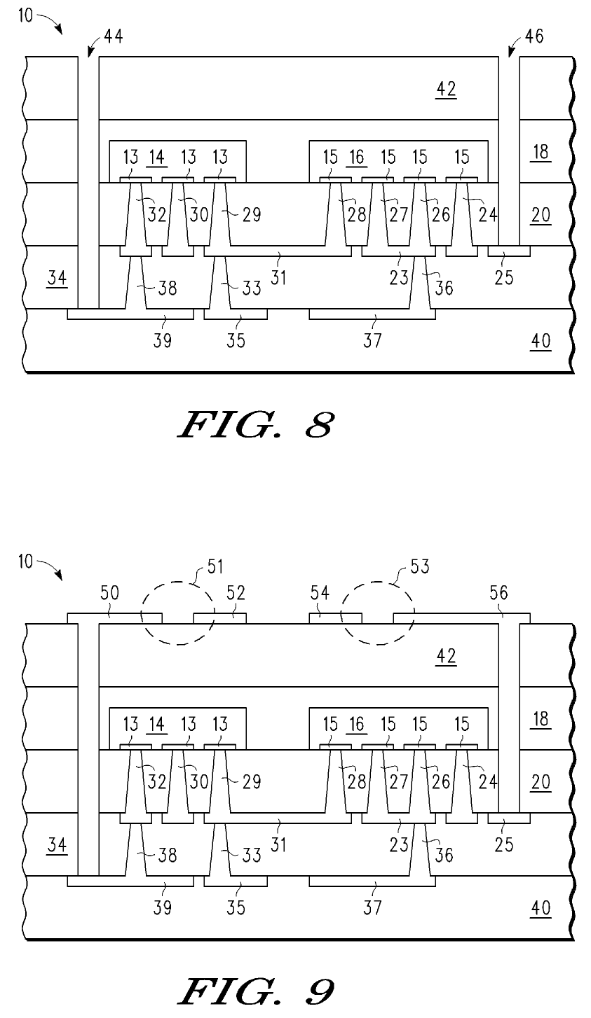

FIG. 8 illustrates panel 10 after formation of a fourth dielectric layer 42 and via-holes 44 and 46, in accordance with one embodiment. Panel 10 is flipped over again, to the orientation illustrated in FIGS. 1 and 2, such that additional processing may be performed over encapsulating layer 18. Fourth dielectric layer 42 is formed over encapsulating layer 18 and over the back sides (or second major surfaces) of semiconductor devices 14 and 16, such that it is formed on an opposite side of encapsulating layer 18 than first dielectric layer 20. That is, note that fourth dielectric layer 42 is located closer to the back sides (or second major surfaces) of semiconductor devices 14 and 16 than the front sides (or first major surfaces) of semiconductor devices 14 and 16, such that semiconductor devices 14 and 16 are located between first dielectric layer 20 and fourth dielectric layer 42. Fourth dielectric layer 42 may be a spun-on polymer or another suitable material. Fourth dielectric layer 42 may be the same material or a different material than any of dielectric layers 20, 34, and 40, and may or may not be formed by the same processes as any of dielectric layers 20, 34, and 40. In one embodiment, fourth dielectric layer 42 is approximately 20 microns thick.

In an alternate embodiment, prior to formation of fourth dielectric layer 42, encapsulating layer 18 may be thinned by removing portions of encapsulating layer 18 which extend beyond the back sides of semiconductor devices 14 and 16 (or beyond the back side of the semiconductor device which extends furthest from first dielectric layer 20). In this embodiment, fourth dielectric layer 42 would be formed in contact with the back sides or second major surfaces of semiconductor devices 14 and 16.

After formation of fourth dielectric layer 42, via-holes 44 and 46 are formed extending through fourth dielectric layer 42, through encapsulating layer 18, and through at least one dielectric layer located over the front sides of devices 14 and 16 (such as through one or more of dielectric layers 20, 34, and 40). That is, via-holes extend at least past semiconductor devices 14 and 16 and through at least one or more of dielectric layers 20, 34, and 40 to be able to route signals appropriately from or to one or more dielectric layers (such as dielectric layer 42) located over encapsulating layer 18, closest to the back sides rather than the front sides of semiconductor devices 14 and 16 to or from one or more dielectric layers (such as any of dielectric layers 20, 34, and 40) located over an opposite side of encapsulating layer 18, closest to the front sides rather than the back sides of semiconductor devices 14 and 16. In the illustrated example, via-hole 44 extends through fourth dielectric layer 42, encapsulating layer 18, first dielectric layer 20, and second dielectric layer 34 to expose interconnect 39, and via-hole 46 extends through fourth dielectric layer 42, encapsulating layer 18, and first dielectric layer 20 to expose interconnect 25. In one embodiment, via-holes 44 and 46 are also referred to as via-through-holes, and may be formed used a laser process or an etch process. Also, in an alternate embodiment, via-holes such as 44 and 46 may be formed through any portion of encapsulating layer 18, or may be formed through either or both of semiconductor devices 14 and 16, or through combinations thereof.

FIG. 9 illustrates panel 10 of FIG. 8 after filling via-holes 44 and 46 and forming interconnects 50, 52, 54, and 56, in accordance with one embodiment. Via-holes 44 and 46 are then filled (or at least partially filled) with any conductive material, such as, for example, copper. The conductive material can be deposited using any suitable process (e.g., chemical vapor deposition (CVD), atomic layer deposition (ALD), plating, the like, and combinations of the above) to fill or partially fill via-holes 44 and 46 and form a thick enough material over fourth dielectric layer 42. The material that lies outside the filled vias and over fourth dielectric layer 42 may be patterned to form interconnects 50, 52, 54, and 56. Note that in one embodiment, the conductor fully fills via-holes 44 and 46; however, in an alternate embodiment, the conductor may partially fill via-holes 44 and 46, such as by coating the inner walls of the via-holes to form hollow tubes of conductor material. In yet another alternate embodiment, conductive studs which may extend through multiple dielectric layers may be present at the location of via-holes 44 and 46. In one example, via-holes 44 and 46 can be filled by placing pre-formed conductive studs in the holes. Alternatively, the conductive studs may be placed earlier in the processing, such as after formation of first dielectric layer 20, where subsequently formed layers are formed around these conductive studs.

In the illustrated embodiment, interconnects 50 and 52 form a first keypad switch point 51 while interconnects 54 and 56 form a second keypad switch point 53. That is, the metal layer over fourth dielectric layer 42 is used to form a keypad switch point grid that can be used with a key pad. In the illustrated embodiment, interconnects 50 and 52 correspond to two contact points of keypad switch point 51, and interconnects 54 and 56 correspond to two contact points of keypad switch point 53. Therefore, each of interconnects 50, 52, 54, and 56 may also be referred to as contacts. Note that any number of dielectric layers may be subsequently formed over fourth dielectric layer 42 to provide sufficient routing of signals, as needed, or to allow for different switch point formations. Note that the interconnects of the keypad switch points are routed back to the opposite side of semiconductor devices 14 and 16 such that they may contact inputs or outputs of a particular semiconductor device, such as semiconductor device 14.

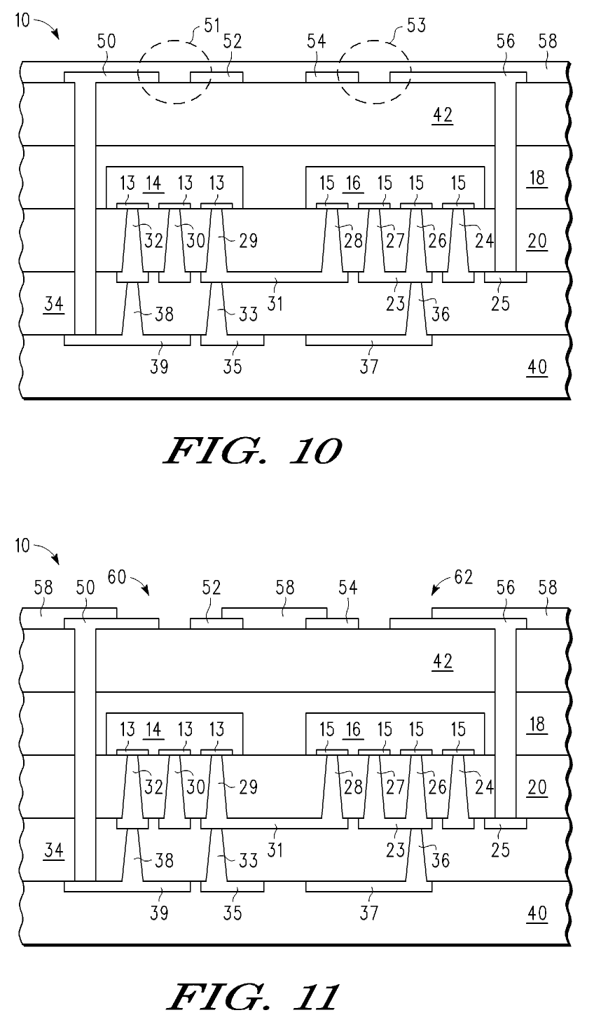

FIG. 10 illustrates panel 10 after formation of a layer 58 over fourth dielectric layer 42 and interconnects 50, 52, 54, and 56, in accordance with one embodiment. Layer 58 is an insulating layer which may be, for example, a dielectric layer or a photo-imageable solder mask layer.

FIG. 11 illustrates panel 10 after forming openings 60 and 62 in layer 58 to expose portions of interconnects 50, 52, 54, and 56 in order to expose keypad switch points 51 and 53, respectively. In this manner, as will be described in more detail below, a keypad can be placed over layer 58 such that when a key of the keypad is depressed, the contact points of the corresponding keypad switch point are shorted to each other. A device having keypad logic can then sense and decode this key press to decipher which key of the keypad was pressed. For example, in the illustrated embodiment, semiconductor device 14 includes such keypad logic, and is coupled to both keypad switch points 51 and 53 (by way of filled via-holes 44 and 46, and by way of other vias and interconnects that may be located in front of or in back of the page, and thus may not be visible in the illustrated cross sections). That is, contacts 50, 52, 54, and 56 are connected to keypad contacts of contacts 13 through dielectric layer 42 and one or more of dielectric layers 20, 34, and 40, where the keypad contacts are used in performing keypad logic functions. Note that semiconductor device 14 may include other logic for performing other functions in addition to the keypad logic function. For example, semiconductor device 14 may be a microprocessor or microcontroller which includes many different functions, including a keypad logic function. Therefore, in one embodiment, some of contacts 13 may be used by semiconductor device 14 in performing keypad logic functions (and thus be referred to as keypad contacts) while others of contacts 13 may be used by semiconductor device 14 in performing other functions.

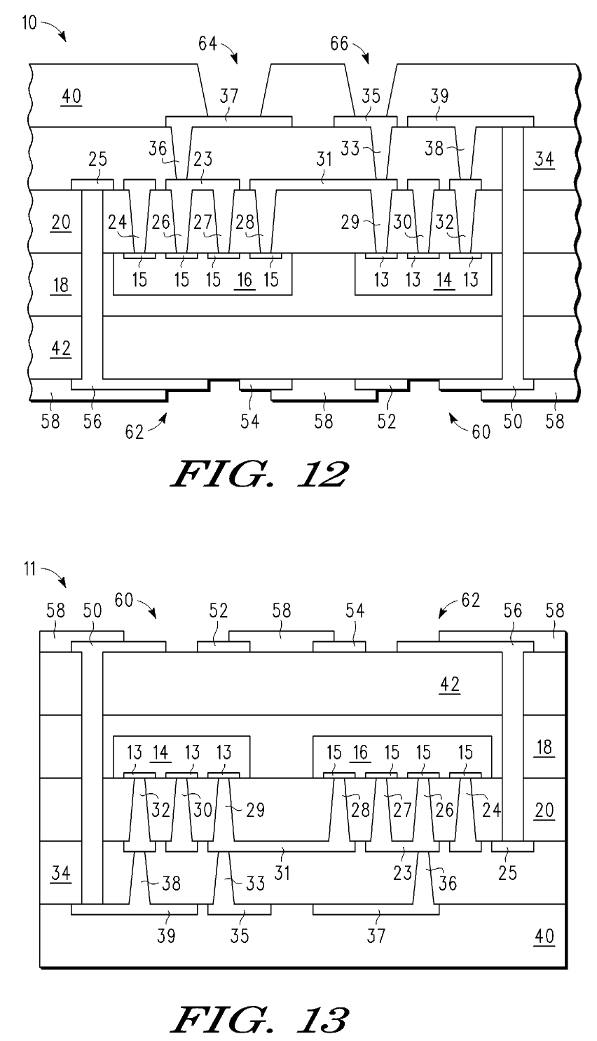

FIG. 12 illustrates panel 10 after forming openings 64 and 66 in third dielectric layer 40, in accordance with one embodiment. That is, panel 10 is again flipped so as to provide access to third dielectric layer 40, and third dielectric layer 40 is patterned and etched to form openings 64 and 66 which expose portions of underlying interconnects 37 and 35, respectively (where each of interconnects 37 and 35 may also be referred to as a contact). In one embodiment, openings 64 and 66 are formed to provide a land grid array for subsequently connecting the illustrated aggregate site (packaged device, once singulated) to a PCB. Alternatively, conductive bumps or balls may be formed within openings 64 and 66 which may be used for subsequently connecting the illustrated aggregate site (packaged device, once singulated) to a PCB.

Note that, in the illustrated embodiments, while openings 60 and 62 expose contacts which are connected to keypad contacts of contacts 13 of semiconductor device 14 (through dielectric layer 42), openings 64 and 66, on an opposite side of panel 10, expose contacts (such as contact 35) which are connected to other, non-keypad, contacts of contacts 13 of semiconductor device 14 (through one or more of dielectric layers 20, 34, and 40 and through dielectric layer 42). In an alternate embodiment, a contact exposed by an opening in dielectric layer 40, such as openings 64 and 66, may also be connected to a keypad contact of contacts 13 of semiconductor device 14, wherein the keypad contact can then be accessed by keypad on one side of the packaged device as well as a contact on the opposite side of the packaged device.

FIG. 13 illustrates panel 10 after singulating, where singulation can occur by any process, such as with a saw, laser or other means. Panel 10 is again flipped for ease of illustration. In the illustrated embodiment, the aggregate site including semiconductor devices 14 and 16, is singulated near semiconductor device 14 on one side and near semiconductor device 16 on the other side, but does not expose semiconductor devices 14 and 16 (where the term “near” in this example may refer to 0.025-inch or within the accuracy limits of the singulation and placement processes). Thus, encapsulating layer 18 (and dielectric layers 20, 34, 40, and 42) are cut to form a singulated packaged device 11 including both semiconductor devices 14 and 16 and including one or more integrated keypad switch points.

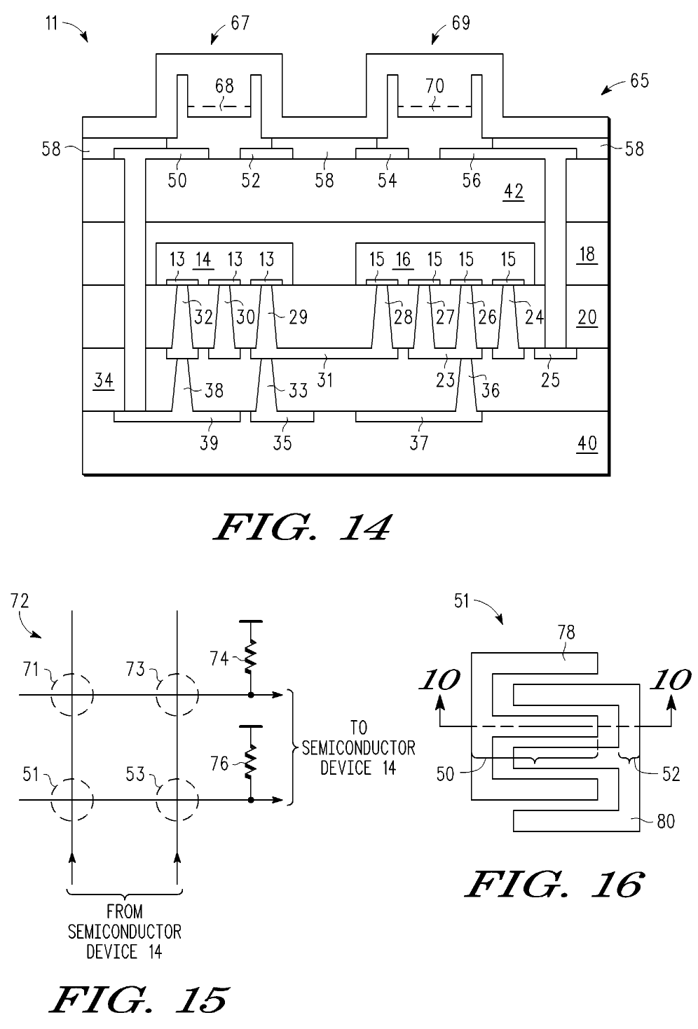

FIG. 14 illustrates packaged device 11 after coupling a keypad 65 over layer 58 and keypad switch points 51 and 53, in accordance with one embodiment. Keypad 65 may be formed of a polymer or other elastic material and includes keypads, such as keypads 67 and 69, corresponding to each switch point of packaged device 11. Each keypad includes a conductive portion within the keypad, such as conductive portions 68 and 70, which can be used to contact the corresponding keypad switch points of packaged device 11 to electrically connect the two contact points of the corresponding keypad switch point. For example, since keypad 65 is formed of an elastic material, when key pad 67 is pressed, conductive portion 68 comes into contact with contacts 50 and 52 of keypad switch point 51 so as to short both contact points of keypad switch point 51. This can then be used by the keypad logic within semiconductor device 14, as will be described below, to decipher which keypad switch point was shorted and thus which key of the keypad was pressed.

FIG. 15 illustrates a top-down view of a keypad grid 72 in accordance with one embodiment. Keypad grid 72 (also referred to as a keypad switch point grid) is a 2 by 2 grid having a four keypad switch points 51, 53, 71, and 73, thus useable in decoding four keypad keys. Note that FIG. 13 may correspond to a cross section taken through the second row of keypad grid 72 which includes keypad switch points 51 and 53. According to one embodiment, each column of keypad grid 72 is driven by semiconductor device 14 (which is assumed to include the keypad logic to send and decode a keypad grid), and each row of keypad grid 72 is provided as inputs to the keypad logic of semiconductor device 14. Note that each row of keypad grid 72 includes a pull-up resistor 74 and 76, respectively, which may be included as discrete elements in packaged device 11, or may be included in the same device having the keypad logic, such as semiconductor device 14.

In operation, each horizontal line is pulled high by the pull-up resistors until a keypad key is pressed, and each vertical line is driven low by the keypad logic in semiconductor device 14. At this point, the pressed key shorts a horizontal line to a vertical line at a corresponding switch point. For example, if the key of the keypad overlying switch point 53 is pressed, then the vertical line going through switch point 53 is shorted to the horizontal line going through switch point 53, thus driving that horizontal line from high to low. Therefore, the keypad logic in semiconductor device 14 detects that the second horizontal line (from top to bottom) has gone low (thus identifying this horizontal line as the selected horizontal line), and proceeds to drive both vertical lines high. That is, at this point, the keypad logic in semiconductor device 14 knows that one of switch points 51 or 53 has been shorted (i.e. selected by the pressed key), and now needs to determine which one. Once the keypad logic in semiconductor device 14 drives all vertical lines of grid 72 high, it drives each line, one at a time, low again to determine which vertical line corresponds to the shorted (i.e. selected) switch point. That is, when vertical line that corresponds to a non-selected switch point is driven high, no change occurs in the selected horizontal line. However, when the vertical line that corresponds to the selected switch point is driven high, the selected horizontal line again goes high since it is shorted to the vertical line that is currently being driven high. Therefore, in the current example, after both vertical lines are driven high, the keypad logic function in semiconductor device 14 drives the first vertical line (from left to right) low and senses that no change has occurred in the selected horizontal line (that is, it stays low). However, when the keypad logic function in semiconductor device 14 drives the second vertical line low, the keypad logic in semiconductor device 14 senses that the selected horizontal line has returned to high. At this point, the keypad logic in semiconductor device 14 can identify that switch point 53 is the selected switch point, and can proceed to decode this to determine what key of the keypad it refers to, such as, for example, through the use of a look-up table.

In an alternate embodiment, the keypad logic in semiconductor device 14 can be constantly polling the vertical lines to determine that a key has been pressed, rather than waiting for the detection of a pressed key (by sensing when a horizontal line has gone low). In yet another alternate embodiment, rather than using a 2×2 grid to decode 4 keys of a keypad, four horizontal lines may be used in combination with a vertical grounded line, where the intersection of each horizontal line and the vertical grounded line corresponds to one of the four keypad switch points. In this case, each of the horizontal lines are provided to the keypad logic within semiconductor device 14 such that when a key is pressed and shorts a selected keypad switch point, the keypad logic can determine which switch point is selected by determining which horizontal line went low. The keypad logic, based on this information, can then proceed to decode this information to determine what key of the keypad it refers to.

Note that many different configurations of switch points and switch point grids may be used, as well as many different methods of sensing and decoding pressed keys may be implemented. That is, any type of logic may be used within keypad logic to perform the function of sensing and decoding pressed keys. Furthermore, the integrated switch points of packaged device 11 can be laid out in many different forms, such as in a grid form, or in a line, etc. Furthermore, each switch point itself can have a variety of different configurations.

FIG. 16 illustrates one example of a configuration for a switch point, such as switch point 51. Note that switch point 51 includes two contact points 78 and 80, where each contact point includes a plurality of digits which are inter-digitated with each other. For example, FIG. 10 may correspond to a cross-section taken through the middle of the switch point 51, where interconnect 50 is a portion of contact 78 and interconnect 52 is a portion of contact 80. In this manner, when a conductive materials, such as a conductive portion of a key of a keypad is contacted against these digits, contacts 78 and 80 are shorted together. Alternatively, other configurations for each switch point may be used. For example, contact 80 may be a circular metal portion while contact 78 may form a ring around the circular metal portion. Note that any physical configuration of the switch points may be used in created an integrated switch point grid for packaged device 11.

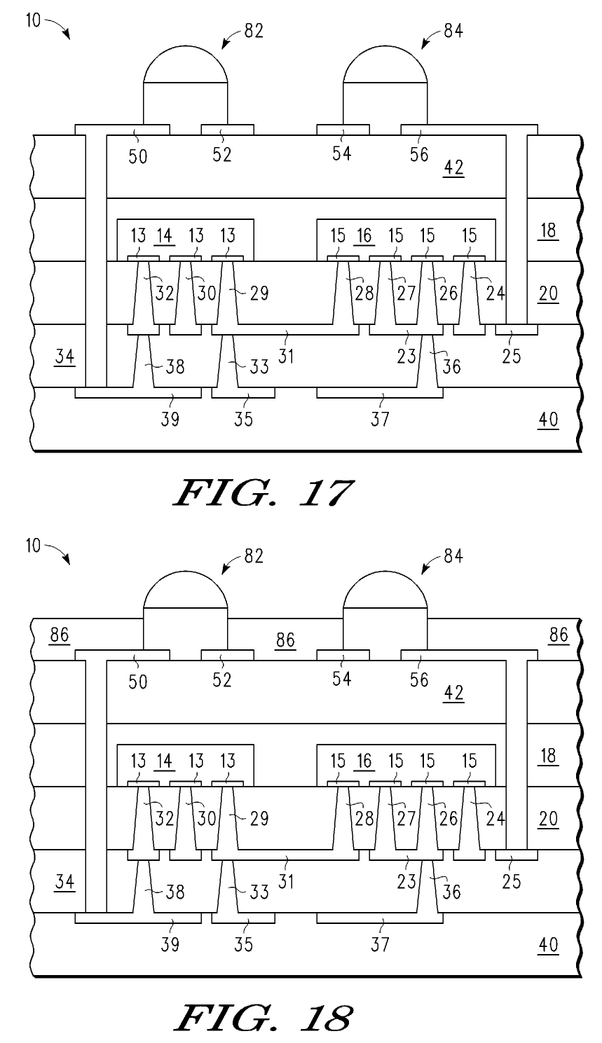

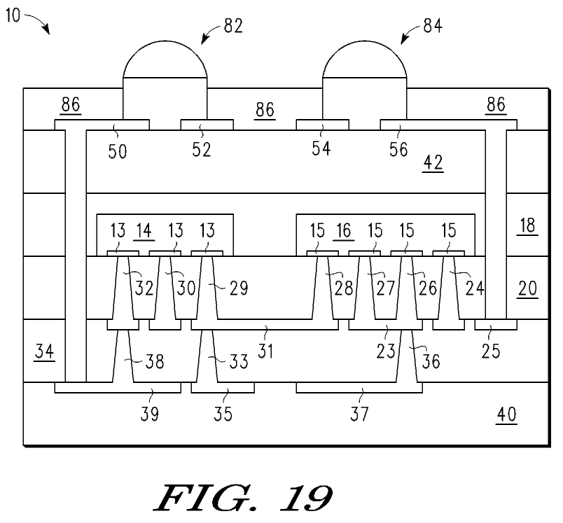

FIG. 17 illustrates a cross-section of panel 10 following the cross-section of FIG. 9, in accordance with one embodiment. In FIG. 10, note that interconnects 50, 52, 54, and 56 were formed, corresponding to switch points 51 and 53. In FIG. 17, popple switches 82 and 84 are placed over switch points 51 and 53, respectively. Each popple switch is a tactile switch that may correspond to a single key of a keypad, and may also simply be referred to as a popple. That is, when a popple is pressed, a conductive portion within the popple comes into contact with its corresponding switch point to short out the contacts of the switch point, in a manner similar to pressing a key of a keypad such as keypad 65. For example, the conductive portion of the popple may be spring loaded such that applying pressure to the popple allows the conductive portion to come into contact with the switch point.

FIG. 18 illustrates panel 10 after the formation of a dielectric layer 86 according to one embodiment. Dielectric layer 86 is formed over fourth dielectric layer 42, interconnects 50, 52, 54, and 56, and surrounding poppies 82 and 84, so as to physically secure the poppies in place over the corresponding switch points. In one embodiment, dielectric layer 42 is formed by pouring a thick liquid over fourth dielectric layer 52, allowing it to form layer 86 around the poppies. Any other suitable process or material can be used to form layer 86.

FIG. 19 illustrates panel 10 after singulating, where singulation can occur by any process, such as with a saw, laser or other means. In the illustrated embodiment, the aggregate site including semiconductor devices 14 and 16, is singulated near semiconductor device 14 on one side and near semiconductor device 16 on the other side, but does not expose semiconductor devices 14 and 16 (where the term “near” in this example may refer to 0.025-inch or within the accuracy limits of the singulation and placement processes). Thus, encapsulating layer 18 (and dielectric layers 20, 34, 40, and 42) are cut to form a singulated packaged device 11 including both semiconductor devices 14 and 16 and including one or more integrated keypad switch points as well as keypads. Therefore, through the use of poppies, such as poppies 82 and 84, a packaged device having an integrated keypad in addition to an integrated keypad switch point grid can be formed.

Therefore, it can now be understood how the formation of dielectric layers over both major surfaces of one or more semiconductor devices or elements within an aggregated site can be used to form an integrated keypad switch point grid, and, in some cases, a keypad as well. Also, the formation of dielectric layers over both major surfaces allows for a packaged device having an integrated keypad switch point grid (with or without integrated keys) to be formed at one major surface while allowing for a land grid array or solder ball connections to be formed at another major surface, opposite the major surface having the integrated keypad switch point grid, for connection to a PCB or to other devices. In this manner, smaller devices can be formed using these types of packaged devices having integrated switch point grids, either with or without integrated keypads. Also, by forming each dielectric layer over either side of semiconductor device 14 or 16, problems (such as sizing and alignment) introduced by attaching a pre-existing layer to an underlying layer, such as in formation of a PCB, are avoided. Also, note that in alternate embodiments, any number of dielectric layers can be used on either side of the aggregate sites of panel 10, depending on the routing and interconnect needs of the devices or elements within each aggregate site. Also, in alternate embodiments, semiconductor device 14 or 16 or both may also include contacts on the back side of the device, opposite the front sides where contacts 13 or 15, respectively, are located. The dielectric layers described herein can therefore also be used to connect keypad switch points or other contacts with these back side contacts as well.

By now it should be appreciated that there has been provided a low cost method for fabricating and embedding a package having an integrated keypad switch point grid, and, in some embodiments, a keypad as well, using a build-up technology for creating a packaged device. The resulting package may be a redistributed chip package (RCP) because the interconnects are routed or redistributed among one or more layers to minimize the area of the package. No wirebonding or traditional substrate (leadframe or package substrate) is needed to form a RCP. This increases yield and decreases cost. Furthermore, no external keypad switch point peripheral is needed in the RCPs described herein, which may further reduce size.

In one embodiment, a method of forming a packaged device having a first semiconductor device having a first major surface and a second major surface includes forming an encapsulating layer over the second major surface of the first semiconductor device and around sides of the first semiconductor device and leaving the first major surface of the first semiconductor device exposed, where the first semiconductor device performs a keypad logic function, and has a first contact having a surface external to the first semiconductor device for use by the first semiconductor device in performing the keypad logic function. The method further includes forming a first dielectric layer over the first major surface, forming a second dielectric layer over the second major surface, and forming a second contact having a surface exposed external to the packaged device over the second dielectric layer that is connected to the first contact through the second dielectric layer.

In a further embodiment, the method further includes coupling a keypad to the packaged device by coupling a keypad to the second contact.

In another further embodiment, the step of forming an encapsulating layer is further characterized by the first semiconductor device being able to perform a first function and having a third contact having a surface external to the first semiconductor device for use by the first semiconductor device for performing the first function. In yet a further embodiment, the method further includes forming a fourth contact having a surface exposed external to the packaged device over the first dielectric layer that is connected to the third contact through the first dielectric layer. The step of forming an encapsulating layer may further be characterized by the first contact being on the second major surface and the second contact being on the first major surface. In yet an even further embodiment, the step of forming an encapsulating layer is further characterized by the first contact and the third contact being on the first major surface of the first semiconductor device. In yet an even further embodiment, the step of forming the second contact is further characterized by the second contact being connected to the first contact through the first dielectric layer. In yet an even further embodiment, the step of forming the second contact is further characterized by forming a first via hole in the first dielectric layer to expose the first contact; forming a first conductive layer in the via hole and over the first dielectric layer; forming a second via hole in the first dielectric layer, the second dielectric layer, and adjoining the first conductive layer; and forming the second conductive layer in the second via hole.

In another further embodiment, the step of forming an encapsulating layer is further characterized by the encapsulating layer being over a second major surface of a second semiconductor device and around sides of the second semiconductor device and leaving a first major surface of the second semiconductor device exposed, and the step of forming the first dielectric layer is further characterized by being formed over the first major surface of the second semiconductor device, the method further comprising further comprising forming an interconnect between the first and second semiconductor devices to connect the first and second semiconductor devices.

In another further embodiment, the method further includes forming a popple switch on the second contact, and forming a third dielectric around the popple switch and over the second dielectric layer.

In another embodiment, a method of forming a packaged device having a first semiconductor device having a first major surface and a second major surface includes forming an encapsulating layer over a second major surface of the first semiconductor device and around sides of the first semiconductor device and leaving the first major surface of the first semiconductor device exposed, where the first semiconductor device performs a first function, performs a keypad logic function, has a first contact having a surface external to the first device for use by the first semiconductor device in performing the first function, and a second contact having a surface external to the first semiconductor device for use by the first semiconductor device in performing the keypad logic function. The method further includes forming a first dielectric layer over the first major surface, forming a third contact having a surface exposed external to the packaged device over the first dielectric layer that is connected to the first contact through the first dielectric layer, forming a second dielectric layer over the second major surface, and forming a fourth contact having a surface exposed external to the packaged device over the second dielectric layer that is connected to the second contact through the second dielectric layer.

In a further embodiment of the another embodiment, the method further includes coupling a keypad to the packaged device by coupling a keypad to the fourth contact.

In another further embodiment of the another embodiment, the step of forming an encapsulating layer is further characterized by the first contact and the second contact being on the first major surface of the first semiconductor device. In yet a further embodiment, the step of forming the fourth contact is further characterized as being connected to the second contact through the first dielectric layer.

In another further embodiment of the another embodiment, the method further includes forming a third dielectric layer over the first dielectric layer, where the step of forming the third contact is further characterized by the third contact being over the third dielectric layer.

In another further embodiment of the another embodiment, the step of forming an encapsulating layer is further characterized by the first contact being on the first major surface and the second contact being on the second major surface of the first semiconductor device.

In another further embodiment of the another embodiment, the step of forming an encapsulating layer is further characterized by being over a second major surface of a second semiconductor device and around sides of the second semiconductor device and leaving a first major surface of the second semiconductor device exposed, the method further including forming an interconnect between the first and second semiconductor devices to connect the first and second semiconductor devices.

In yet another embodiment, a method of forming a packaged device having a first semiconductor device and a second semiconductor device each having a first major surface and a second major surface includes forming an encapsulating layer over the second major surface of the first and second semiconductor devices and around sides of the first and second semiconductor devices and leaving the first major surface of the first and second semiconductor devices exposed. The first semiconductor device performs a first function, and has a first contact having a surface external to the first semiconductor device for use by the first semiconductor device in performing the first function. The second semiconductor device performs a keypad logic function, has a second contact having a surface external to the second semiconductor device for use by the second semiconductor device in performing the keypad function. The method further includes forming a first dielectric layer over the first major surface of the first and second semiconductor devices, forming a second dielectric layer over the second major surface of the first and second semiconductor devices, forming a third contact having a surface exposed external to the packaged device over the first dielectric layer that is connected to the first contact through the first dielectric layer, forming a fourth contact having a surface exposed external to the packaged device over the second dielectric layer that is connected to the second contact through the second dielectric layer, and forming an interconnect between the first and second semiconductor devices to connect the first and second semiconductor devices.

In a further embodiment of the yet another embodiment, the method further includes coupling a keypad to the packaged device by coupling the keypad to the fourth contact.

In another further embodiment of the yet another embodiment, the step of forming the encapsulating layer is further characterized by the second semiconductor device performing a second function and having a fifth contact having a surface external to the second semiconductor device for use by the second semiconductor device in performing the second function, the method further including attaching a popple switch to the fourth contact, surrounding the popple switch with a third dielectric layer formed over the second dielectric layer, and forming a sixth contact having a surface exposed external to the packaged device over the first dielectric layer that is connected to the fifth contact through the first dielectric layer.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of the present invention.

Benefits, advantages, solutions to problems, and any element(s) that may cause any benefit, advantage, or solution to occur or become more pronounced are not to be construed as a critical, required, or essential feature or element of any or all the claims. The terms “a” or “an”, as used herein, are defined as one or more than one even if other elements are clearly stated as being one or more in the claims or specification. The term “plurality”, as used herein, is defined as two or more than two. The term “another”, as used herein, is defined as at least a second or more. The term “coupled”, as used herein, is defined as connected, although not necessarily directly, and not necessarily mechanically. Moreover, the terms “front”, “back”, “top”, “bottom”, “over”, “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

What is claimed is:

1. A method of forming a packaged device having a first semiconductor device having a first major surface and a second major surface, comprising:
forming an encapsulating layer over the second major surface of the first semiconductor device and around sides of the first semiconductor device and leaving the first major surface of the first semiconductor device exposed, wherein the first semiconductor device:
performs a keypad logic function; and
has a first contact having a surface external to the first semiconductor device for use by the first semiconductor device in performing the keypad logic function;
forming a first dielectric layer over the first major surface;
forming a second dielectric layer over the second major surface; and
forming a second contact having a surface exposed external to the packaged device over the second dielectric layer that is connected to the first contact through the second dielectric layer.

2. The method of claim 1, further comprising:
coupling a keypad to the packaged device by coupling a keypad to the second contact.

3. The method of claim 1, wherein the step of forming an encapsulating layer is further characterized by the first semiconductor device:
being able to perform a first function; and
having a third contact having a surface external to the first semiconductor device for use by the first semiconductor device for performing the first function.

4. The method of claim 3, further comprising forming a fourth contact having a surface exposed external to the packaged device over the first dielectric layer that is connected to the third contact through the first dielectric layer.

5. The method of claim 4, wherein the step of forming an encapsulating layer is further characterized by the first contact and the third contact being on the first major surface of the first semiconductor device.

6. The method of claim 5, wherein the step of forming the second contact is further characterized by the second contact being connected to the first contact through the first dielectric layer.

7. The method of claim 6, wherein the step of forming the second contact is further characterized by:
forming a first via hole in the first dielectric layer to expose the first contact;
forming a first conductive layer in the via hole and over the first dielectric layer;
forming a second via hole in the first dielectric layer, the second dielectric layer, and adjoining the first conductive layer; and
forming the second conductive layer in the second via hole.

8. The method of claim 4, wherein the step of forming an encapsulating layer is further characterized by the first contact being on the second major surface and the second contact being on the first major surface.

9. The method of claim 1, wherein:
the step of forming an encapsulating layer is further characterized by the encapsulating layer being over a second major surface of a second semiconductor device and around sides of the second semiconductor device and leaving a first major surface of the second semiconductor device exposed; and
the step of forming the first dielectric layer is further characterized by being formed over the first major surface of the second semiconductor device;
further comprising forming an interconnect between the first and second semiconductor devices to connect the first and second semiconductor devices.

10. The method of claim 1 further comprising:
forming a popple switch on the second contact; and
forming a third dielectric around the popple switch and over the second dielectric layer.

11. A method of forming a packaged device having a first semiconductor device having a first major surface and a second major surface, comprising:
forming an encapsulating layer over a second major surface of the first semiconductor device and around sides of the first semiconductor device and leaving the first major surface of the first semiconductor device exposed, wherein the first semiconductor device:
performs a first function;
performs a keypad logic function;
has a first contact having a surface external to the first device for use by the first semiconductor device in performing the first function; and
a second contact having a surface external to the first semiconductor device for use by the first semiconductor device in performing the keypad logic function;
forming a first dielectric layer over the first major surface;
forming a third contact having a surface exposed external to the packaged device over the first dielectric layer that is connected to the first contact through the first dielectric layer;
forming a second dielectric layer over the second major surface; and
forming a fourth contact having a surface exposed external to the packaged device over the second dielectric layer that is connected to the second contact through the second dielectric layer.

12. The method of claim 11, further comprising:
coupling a keypad to the packaged device by coupling a keypad to the fourth contact.

13. The method of claim 11, wherein the step of forming an encapsulating layer is further characterized by the first contact and the second contact being on the first major surface of the first semiconductor device.

14. The method of claim 13, wherein the step of forming the fourth contact is further characterized as being connected to the second contact through the first dielectric layer.

15. The method of claim 11, further comprising forming a third dielectric layer over the first dielectric layer, wherein the step of forming the third contact is further characterized by the third contact being over the third dielectric layer.

16. The method of claim 11, wherein the step of forming an encapsulating layer is further characterized by the first contact being on the first major surface and the second contact being on the second major surface of the first semiconductor device.

17. The method of claim 11, wherein the step of forming an encapsulating layer is further characterized by being over a second major surface of a second semiconductor device and around sides of the second semiconductor device and leaving a first major surface of the second semiconductor device exposed, further comprising forming an interconnect between the first and second semiconductor devices to connect the first and second semiconductor devices.

18. A method of forming a packaged device having a first semiconductor device and a second semiconductor device each having a first major surface and a second major surface, comprising:
forming an encapsulating layer over the second major surface of the first and second semiconductor devices and around sides of the first and second semiconductor devices and leaving the first major surface of the first and second semiconductor devices exposed,
wherein the first semiconductor device:
performs a first function; and
has a first contact having a surface external to the first semiconductor device for use by the first semiconductor device in performing the first function;
wherein the second semiconductor device:
performs a keypad logic function; and
has a second contact having a surface external to the second semiconductor device for use by the second semiconductor device in performing the keypad function;
forming a first dielectric layer over the first major surface of the first and second semiconductor devices;
forming a second dielectric layer over the second major surface of the first and second semiconductor devices;
forming a third contact having a surface exposed external to the packaged device over the first dielectric layer that is connected to the first contact through the first dielectric layer;
forming a fourth contact having a surface exposed external to the packaged device over the second dielectric layer that is connected to the second contact through the second dielectric layer; and
forming an interconnect between the first and second semiconductor devices to connect the first and second semiconductor devices.

19. The method of claim 18 further comprising coupling a keypad to the packaged device by coupling the keypad to the fourth contact.

20. The method of claim 18, wherein the step of forming the encapsulating layer is further characterized by the second semiconductor device performing a second function and having a fifth contact having a surface external to the second semiconductor device for use by the second semiconductor device in performing the second function, further comprising:
attaching a popple switch to the fourth contact;
surrounding the popple switch with a third dielectric layer formed over the second dielectric layer, and
forming a sixth contact having a surface exposed external to the packaged device over the first dielectric layer that is connected to the fifth contact through the first dielectric layer.
